(19) United States
(12) Patent Application Publication
(10) Pub. No.: US 2005/0112503 A1
(43) Pub. Date: May 26, 2005

(54) Developing solution for photoresist

(76) Inventors: Takashi Kanda, Niigata (JP); Masaki Kondo, Niigata (JP)

Correspondence Address: EDWARDS & ANGELL, LLP, P.O. BOX 55874, BOSTON, MA, 02205, US

(21) Appl. No.: 10/498,724

(22) PCT Filed: Dec. 13, 2002
(86) PCT No.: PCT/JP02/13103

(30) Foreign Application Priority Data
Dec. 14, 2001 (JP) 2001-382220

(51) Int. Cl. H01L 21/31; H01L 21/469

(52) U.S. Cl. 430/311; 438/758

(57) ABSTRACT

A novel developing solution for photoresists which contains an alkali builder, a fluorine-free surfactant which is a phosphonic acid or phosphate, and a fluorinated surfactant.

### FIELD IN INDUSTRY

The present invention is related to a developing solution for photoresist.

1. Prior Art

In recent years, use of a photoresist having additionally an epoxy-containing substance in the traditional resist has been proposed in order to obtain higher performance in production of WL-CSP. For such a photoresist, it is necessary to use a more alkaline developer since its solubility in the traditional developing solution is low. However, if the alkalinity is too strong, the problem is that undercut occurs during pier [phonetic] formation.

Accordingly, a developing solution without the above problem has been in demand.

2. Disclosure of Invention

The inventors found that by using the combination of a fluorine-free surface-active agent and a fluorinated surface-active agent, the above problem can be solved.

Thus, the present invention is related to a developing solution for photoresist. The developing solution contains an alkali builder, a fluorine-free surface-active agent and a fluorinated surface-active agent.

For the alkali builder, any alkaline substance can be used, such as alkali metal hydroxides (e.g. sodium hydroxide, potassium hydroxide, and lithium hydroxide), alkali metal silicates (e.g. sodium orthosilicate, potassium orthosilicate, sodium metasilicate, and potassium metasilicate), alkali metal phosphates (e.g. tertiary sodium phosphate, and tertiary potassium phosphate), etc. These compounds can be used individually or, if necessary, in combination of two or more compounds. Preferably, the alkali builder is potassium hydroxide.

The present developing solution is alkaline, preferably with a pH of at least 12, more preferably at least 13.

The fluorine-free surface-active agent used in the developing solution of the present invention is a phosphonic acid or phosphate, preferably an alkylphenoxy-polyalkoxyalkyl phosphate, most preferably octylphenoxypolyethoxyethyl phosphate. Fluorine-free surface-active agents, if necessary, can be used in combination of two or more compounds.

The amount of the fluorine-free surface-active agent added should be appropriately determined experimentally. Typically, the amount added is from 0.01 g/L to 10 g/L, more typically from 0.1 g/L to 5 g/L.

The fluorinated surface-active agent is any compounds with at least one fluorine atom and with surface-active function.

The fluorinated surface-active agent can be any known surface-active agents, such as perfluoroalkyl-containing oligomers, perfluoroalkyl sulfonate, perfluoroalkyl carboxylate, perfluoroalkyl phosphate, perfluoroalkyl ammonium iodide, perfluoroalkylamine oxide, perfluoroalkyltrimethylammonium, etc. Preferably a perfluoroalkyl-containing oligomer or perfluoroalkyl sulfonate is used. These compounds can be available, for example, from Dainippon Ink Chemistry Corp., Ltd. as MEGAFAC F-179 and F-160, respectively. These compounds can be used individually or, if necessary, in combination of two or more compounds.

The amount of the fluorinated surface-active agent added should be appropriately determined experimentally. Typically, the amount added is from 0.001 g/L to 10 g/L, more typically from 0.01 g/L to 5 g/L.

The present developing solution is preferably used for the development of the alkali-soluble photoresist containing an epoxy-containing substance.

Thus, the present invention is related to a method for forming photoresist relief image, consisting of
1) coating an alkali-soluble photoresist composition containing an epoxy-containing substance, and
2) exposing and then developing the layer of the photoresist composition on the base body to obtain a photoresist relief image. The developing solution used is the developing solution of the present invention.

The photoresist used in the present invention contains an epoxy-containing substance. The epoxy-containing substance is any organic compound with at least one oxirane ring that can be polymerized by ring opening. This substance is called epoxide in a broad sense. It includes monomer epoxy compounds, aliphatic, alicyclic, aromatic and heterocyclic oligomer and polymer epoxides. Such a preferable substance usually has at least two polymerizable epoxy groups per molecule. The polymer epoxide includes linear polymers with terminal epoxy groups (such as diglycidyl ether of polyoxyalkylene glycol), polymers with skeletal oxirane units (such as polybutadiene polyepoxide), and polymers with side-chain epoxy groups (such as glycidyl methacrylate polymer or copolymer). The epoxide can be a pure compound, or, usually, a mixture containing one, two or more epoxy groups per molecule.

Useful epoxy-containing substances are various, from low molecular weight monomeric substances and oligomers to relatively high molecular weight polymers. The main chains and substituent groups are also highly varied. For example, the main chain can be of any type, while the substituent groups can be any one except those that react with the oxirane ring at room temperature. Specific examples of an appropriate substituent group include halogens, ester groups, ethers, sulfonate group, siloxane group, nitro group, and phosphate group.

Another useful epoxy-containing substance in the present invention is glycidyl ether. Specific examples include multivalent phenol ethers [for example, diglycidyl ether of 2,2-bis-(2,3-epoxy-propoxyphenol)propane] obtained by a reaction between a multivalent alcohol and an excess of a chlorohydrin (for example, epichlorohydrin). Other specific examples of this type of epoxide are described in U.S. Pat. No. 3,018,262. There are many commercially available epoxy-containing substances that can be used in the present invention. In particular, readily available epoxides include epichlorohydrin, glycidol, glycidyl methacrylate, diglycidyl ether of p-tert-butylphenol (for example, the product with a trade name of Epi-Rez 5014 made by Celanese), diglycidyl ether of bisphenol A (e.g. the products with trade names of Epon 828, Epon 1004 and Epon 1010, respectively, made by the Shell Chemical Co., and Der-331, Der-332 and Der-334 made by the Dow Chemical Co.), vinyl cyclohexenedioxide (e. g. ERL-4206 made by Union Carbide Corp.), 3,4-epoxy-6-methyl-cyclohexylmethyl-3,4-epoxy-6-methylcyclohexene carboxylate (e. g. ERL-4201 made by Union Carbide Corp.), bis(3,4-epoxy-6-methylcyclohexylmethyl) adipate (e. g. ERL-4289 made by Union Carbide Corp.), bis(2,3-epoxycyclopentyl) ether (e. g. ERL-0400 made by Union Carbide-Corp.), polypropylene glycol-modified aliphatic epoxy (e. g. ERL-4050 and ERL-4269 made by Union Carbide Corp.), dipentene dioxide (e. g. ERL-4269 made by Union Carbide Corp.), non-inflammable epoxy resin (e. g. the brominated bisphenyl type epoxy resin DER-580 made by the Dow Chemical Co.), 1,4-butanediol diglycidyl ether of phenol formaldehyde novolac (e. g. DEN-431 and DEN-438 made by the Dow Chemical Co.), and resorcinol diglycidyl ether (e.g. Kopoxite made by the Koppers Company, Inc.).

The photoresist used in the present invention can contain a resin binder having no epoxy group.

The resin binder can be any substance that undergoes photo-crosslinking reaction with at least one component of the composition. An appropriate resin includes one with a functional group having at least one reactive portion such as a reactive hydrogen. Phenol resin is a particularly appropriate reactive resin. It is preferably used at a concentration sufficient for developing the coated layer of the composition with an aqueous or semi-aqueous solution. An appropriate phenol resin includes the phenol aldehyde condensation product known as novolac resin in the industry, homopolymer and copolymer of alkenyl phenol, partially hydrogenated novolac and poly(vinyl phenol) resin, and homopolymer and copolymer of N-hydroxyphenyl-maleimide.

Among the phenol resins appropriate as the resin binder, phenol formaldehyde novolac is a preferable substance. The reason is that novolac can form a coating composition for forming photoimage, which can be developed with an aqueous solution. These resins are produced by standard methods described in many publications, such as DeForest Photoresist Materials and Processes, McGraw-Hill Book Company, New York, Ch. 2, 1975; Moreau, Semiconductor Lithography Principles, Practices and Materials, Plenum Press, New York, Chs. 2 and 4, 1988; and Knop and Pilato, Phenolic Resins, Springer-Verlag, 1985.

Novolac resin is a thermal setting condensation product of phenol and aldehyde. Specific examples of phenols suitable for the condensation with an aldehyde, particularly formaldehyde, for production of novolac resin include phenol, m-cresol, o-cresol, p-cresol, 2,4-xylenol, 2,5-xylenol, 3,4-xylenol, 3,5-xylenol, thymol, and their mixtures. By an acid-catalyzed condensation reaction, an appropriate novolac resin with a molecular weight of about 500-100,000 dalton is produced.

Another preferable phenol resin is poly(vinyl phenol). Poly(vinyl phenol) resin is a thermal setting material that can be formed by block polymerization, emulsion polymerization or solution polymerization of corresponding monomer in the presence of a cation catalyst. Vinyl phenol used in the production of poly(vinyl phenol) resin can be prepared by, for example, hydrolysis of commercially available coumarin or substituted coumarin followed by decarboxylation of the resultant hydroxycinnamic acid. It also can be prepared by decarboxylation of hydroxycinnamic acid obtained by dehydration of hydroxyalkylphenol or by a reaction between substituted or unsubstituted hydroxybenzaldehyde and malonic acid. The preferable poly(vinyl phenol) resin prepared using such a vinyl phenol has a molecular weight of about 2,000- about 100,000 dalton. U.S. Pat. No. 4,439,516 also discloses the method for producing poly(vinyl phenol) resin.

Another appropriate reactive resin is a polymer having a structure similar to that of novolac resin or poly(vinyl phenol) resin and containing phenol units and non-aromatic cyclic alcohol units. This type of copolymer is described in European Patient Application Publication No. 0401499 published on Dec. 12, 1990.

An additional appropriate phenol type reactive resin is homopolymer or copolymer of N-hydroxyphenyl maleimide. This type of substance is described in European Patient Application Publication No. 0255989, from page 2, line 45 to page 5, line 51.

The photoresist used in the present invention preferably contains an amine base substance as a cross-linking agent, such as melamine monomer, oligomer or polymer, various resins such as melamine formaldehyde, benzoguanamine-formaldehyde, urea-formaldehyde, glycolyl-formaldehyde resin, or their combination. Particularly suitable cross-linking agents includes the melamine produced by American Cyanamid Company located in Wayne, N.J., such as Cyme 1 (registered trade mark) 300, 301, 303, 350, 370, 380, 1116 and 1130, benzoguanamine such as Cymel (registered trade mark) 1123 and 1125, the glycolyl resin Cymel (registered trade mark) 1170, 1171 and 1172, and the urea-based resin Beetle (registered trade mark) 60, 65 and 80. Many other similar amine base compounds are commercially available from various manufacturers.

Among the above amine cross-linking agents, melamine resin is the preferred one. In particular, melamine formaldehyde resin is preferable, that is, the product from a reaction between melamine and formaldehyde. These resins are usually ethers such as trialkylolmelamine and hexaalkylolmelamine. The alkyl group can contain 1-8 or more carbon atoms, but methyl is the preferable one. Depending on reaction conditions and concentration of formaldehyde, more complex units can be formed by interaction of methyl ether.

The photoresist composition used in the present invention further contains a radiation-sensitive component. The radiation-sensitive component usually is an additive in the composition. However, in the composition the radiation-sensitive component also can form a part of a different component of the composition, such as the resin binder containing a photoactive side chain, or a photoactive group as a unit of the polymer chain of the binder.

The radiation-sensitive component is selected from compounds that can form an acid upon activation by radiation (that is, acid-forming substances), and compounds that can form a base upon activation by radiation (that is, base-forming substances).

Any known radiation-sensitive component can be used.

Normally, a preferable photo-acid-forming substance is an onium salt, more preferably an onium salt with a weakly nucleophilic anion. The above anion is a metal or non-metal with 2-7 valences, such as Sb, Sn, Fe, Bi, Al, Ga, In, Ti, Zr, Sc, D, Cr, Hf, Cu and anions of halogen complex of B, P and As. Specific examples of an appropriate onium salt include diaryl diazonium salts, onium salts of groups Va, Vb, Ia, Ib and I in the Periodic Table of Elements, such as halonium salts (in particular, aromatic iodonium and iodoxonium salts), quaternary ammonium, phosphonium and alusonium [phonetic] salts, aromatic sulfonium salts, sulfoxonium salts, and selenonium salts.

Another appropriate acid-forming substance is the iodonium salt. This type of preferable salt is formed from, for example, as described in U.S. Pat. No. 4,683,317, an aryl iodosotosylate and an aryl ketone.

Among the acid-forming substances, at least several nonionic organic compounds are appropriate. Preferable nonionic organic acid-forming substances include halogenated nonionic compounds (such as 1,1-bis[p-chlorophenyl]-2,2,2-trichloroethane (DDT), 1,1-bis[p-methoxyphenyl]-2,2,2-trichloroethane (Methoxychlor (registered trade mark)), 1,2,5,6,9,10-hexabromocyclododecane, 1,10-dibromodecane, 1,1-bis[p-chlorophenyl]2,2-dichloroethane, 4,4′-dichloro-2-(trichloromethyl)benzhydrol, 1,1-bis(chlorophenyl)2-2,2-trichloroethanol (Kelthane (registered trade mark)), hexachlorodimethylsulfone, 2-chloro-6-(trichloromethyl)pyridine, O,O-diethyl-O-(3,5,6-trichloro-2-pyridyl)phosphorothioate (Dursban (registered trade mark), 1,2,3,4,5,6-hexachlorocyclohexane, N-(1,1-bis[p-chlorophenyl]-2,2,2-trichloroethylacetamide, tris[2,3-dibromopropyl]isocyanurate, 2,2-bis[p-chlorophenyl]-1,1-dichloroethylene, and their isoforms, analogues, and residual compounds. Among these substances, tris[2,3-dibromopropyl]isocyanurate is particularly preferable. Appropriate acid-forming substances are described in European Patent Application Publication No. 0232972. The above-mentioned residual compounds are formed during the synthesis of the above halogenated organic compounds and thus can be present in a small amount in products containing such an organic compound in a large quantity. Thus, they are impurities or other modified substances closely related to the above halogenated organic compounds.

An appropriate base-forming compound forms a base by photodecomposition upon exposure to activating radiation (for example, photo-opening). A base-forming substance normally is a neutral compound forming a base (for example, an organic base such as amine) upon photo-activation. Various base-forming substances are considered to be suitable for the use in the present composition. Appropriate base-forming substances can be organic compounds, such as photo-reactive carbamates including benzyl carbamate and benzoin carbamate. Other appropriate base-forming substances include O-carbamoyl hydroxylamine, O-carbamoyl oxime, aromatic sulfonamide, α-lactone, and amide compounds such as N-(2-aryl-ethynyl)amide and other amides.

Particularly preferable organic base-forming substances include 2-hydroxy-2-phenylacetophenone-N-cyclohexylcarbamate, o-nitrobenzyl-N-cyclohexylcarbamate, N-cyclohexyl-2-naphthalenesulfoneamide, 3,5-dimethoxybenzyl-N-cyclohexylcarbamate, N-cyclohexyl-p-toluenesulfonamide and dibenzoin isophorone dicarbamate.

A metal coordination complex forming a base upon exposure to activating radiation, such as the cobalt (III) complex described in J. Coatings Tech., 62, no. 786, 63-67 (June, 1990) is also an appropriate substance.

The photo-acid- or photo-base-forming substance is contained in the photoresist in an amount sufficient for developing the coating layer of the composition by exposure to activating radiation or, if necessary, after post-exposure baking. More specifically, the photo-acid- or photo-base-forming substance is normally is used at about 1-15 wt % against entire solid materials of the composition, more typically at a concentration of about 1-6 wt % against the entirety of solid materials of the composition. However, the concentration of the photo-reactive component can be changed depending on particular substance used.

The compound containing at least one electrophilic multiple bond is at least a cross-linking agent suitable for the composition containing the photo-base-forming compound. Specific examples of the electrophilic multiple bond include maleimide, α,β-unsaturated ketone, ester, amide, nitrile and other α,β-unsaturated electrophilic groups.

Among the cross-linking agents containing an electrophilic multiple bond, substances containing at least one maleimide group are particularly preferable. In particular, bismaleimide is preferable. A particularly preferable compound is 1,1′-(methylenedi-1,4-phenylene)bismaleimide. The other appropriate maleimide can be easily synthesized by known methods, such as heat- or acid-condensation reaction of maleic anhydride with a compound with a structure corresponding to R(NH₂)₂ [in the structure, R is as described in formula (I)]. See I. Varma et al., Polymer News, Vol. 12, 294-306 (1987) for reference for this reaction.

The electrophilic multiple bond-containing resin or the resin containing epoxy and electrophilic multiple bond also can be used in the composition of the present invention as an appropriate cross-linking agent. Many appropriate resins are commercially available, such as the bismaleide resin with a trade name of Kerimid made by Rhone-Poulenc, and the bismaleide resin with the trade name of Thermax MB-8000 made by Kennedy and Klim, Inc. Appropriate bismaleide resins are also described in the above mentioned I. Varma et al.'s paper and in U.S. Pat. No. 4,987,264.

Other appropriate cross-linking agents include aromatic compounds with at least one allyl substituent group (that is, aromatic compounds with at least one of the positions on the ring substituted by an allyl carbon of an alkylene group). Appropriate allyl aromatic compounds include allylphenyl compounds. More preferable are allylphenol compounds. The allylphenol hardening agent can be a monomer, oligomer or polymer with at least one phenol unit and with at least one of the ring positions on the phenol unit(s) substituted by an allyl carbon of an alkylene group.

In general, an appropriate concentration of at least one cross-linking agent is about 5-30 wt % of entire solid material of the composition, preferably about 10-20 wt % of the entire solid materials.

In the photoresist composition used in the present invention, a photosensitizing agent is also used as a preferable additive. It is added in the composition in an amount sufficient to increase the wavelength sensitivity. Appropriate sensitizing agents include, for example, 2-ethyl-9,10-dimethoxyanthracene, 9,10-dichloroanthracene, 9,10-phenylanthracene, 1-chloroanthracene, 2-methylanthracene, 9-methylanthracene, 2-t-butylanthracene, anthracene, 1,2-benzanthracene, 1,2,3,4-dibenzanthracene, 1,2,5,6-dibenzanthracene, 1,2,7,8-dibenzanthracene, 9,10-dimethoxydimethylanthracene, etc. Preferable sensitizing agents are 2-ethyl-9,10-dimethoxyanthracene, N-methylpheno-thiazine and isopropylthioxantone.

The photoresist composition used in the present invention can contain any other additives such as dyestuff, filler, moisturizing agent, flame retardant, etc. Appropriate filler includes, for example, TALC (a product made by Cyprus Chemical), while an appropriate dyestuff includes Orasol Blue made by Ciba-Geigy.

The filler and dyestuff can be used at a high concentration, for example, at 5-30 wt % of entire solid materials of the composition. The other additives, such as moisturizing agent, foaming agent, dye dispersing agent, etc. are usually contained at a low concentration, for example, lower than about 3 wt % of the entirety of the solid materials of the composition.

For producing the liquid coating composition, the components of the compositions are dissolved in an appropriate solvent, such as at least one chosen from glycol ether from ethylene glycol monomethyl ether, propylene glycol monomethyl ether, and dipropylene glycol monomethyl ether, ester (e.g., methylcellosolve acetate, ethylcellosolve acetate, propylene glycol monomethyl ether acetate, and dipropylene glycol monomethyl ether acetate), other solvents (e. g., dibasic ester, propylene carbonate, γ-butyrolactone, etc.), and alcohols (e. g., n-propanol).

To produce the liquid coating composition, dry components are dissolved in the solvent. The concentrations of the solids are dependent on several factors including a method for its application onto the base body. In general, the concentration of the solids in the solvent can be at least about 10-70 wt % of the total weight of the coating composition. More specifically, for a flow-coating composition, the solid concentration can be at least 40-50 wt % of total weight of the composition.

The photoresist composition can be coated onto the base body by a general method, such as screen printing, flow coating, roller coating, slot coating, spin coating, electrostatic blowing, blow coating, or soaking coating, or as a dry film. As described above, the viscosity of the photoresist can be adjusted in accordance with the particular method used, by, for example, by adding more solvent for a method requiring a low viscosity, or adding a thickening agent along with a filler for a method requiring a high viscosity.

After coating, the layer of the liquid composition is dried to remove the solvent, and, if necessary, is heated to induce cross-linking.

Thus, the present invention provides a method to form a photoresist relief image, consisting of
1) coating an alkali-soluble photoresist composition containing an epoxy-containing substance onto a base body, and
2) exposing and then developing the layer of the photoresist composition on the base body to obtain a photoresist relief image. The developing solution is the developing solution of the present invention.

The photoresist used in the present invention can be the negative or positive type. After exposure and, if necessary, cross-linking, the non-exposed portions (for negative type) or exposed portions (for positive type) are removed by the developing solution, thereby forming a relief image.

With the developing method of the present invention, the relief image formed by the epoxy-containing substance-containing, alkali-soluble photoresist composition can be obtained nicely.

Using the resultant relief image, a circuit can be formed by various treatments by standard methods.

Best Embodiment of the Invention

In the following, the present invention is further described in detail by way of practical examples. The practical examples are described as examples, but are not intended to limit the scope of the present invention.

### PRACTICAL EXAMPLES

### Development Test

A photoresist containing a novolac resin at about 25 wt %, a bisphenol A type epoxy resin at about 30 wt %, a solvent at about 40 wt % and other components such as initiator at about 5 wt % was used to perform the experiment.

The composition was coated at a thickness of about 10 microns using a spin coater. After baking at 90° C. for 30 min in a convection oven, exposure at 1000 mJ was performed using USHIO UV1000SA (USHIO Denki Corp., Ltd.). After baking at 70° C. for 20 min, development was performed at 35° C. for 2-3 min, followed by rinsing with deionized water for 3 min.

### Comparative Example 1

A developing solution with the following composition was used, and the resultant 50-20 micron pier [phonetic] shape was examined in metal microscope or scanning electron microscope.

| | |
|---|---|
| Citric acid | 0.005M |
| Chelating agent | 0.005M |
| CaCl₂.H₂O | 0.005M |
| KOH solution | 0.42N |
| Triton QS-44 | 3 g/L |

Note)
The chelating agent was 1-hydroxyethylidene-1,1-diphosphonic acid, used at 0.005M.
Triton QS-44 is a surface-active agent. It is octylphenoxypolyethoxyethyl phosphate made by Union Carbide. The amounts added were by weight of product.

The resultant profile of pier [phonetic] exhibited an undercut.

### Experimental Examples and Comparative Examples

The same experiment as Comparative Example 1 was performed, except that a surface-active agent, type and amount shown in the table, was used in the developing solution with all the other conditions remaining the same.

C and E in Practical Example Nos. denote comparative and experimental examples, respectively.

| Practical | | addition | | | pier |
|---|---|---|---|---|---|
| example | | amount | Triton | | [phonetic] |
| No. | type of surface-active agent | (g/L) | QS-44 | precipitate | profile |
| C1 | MEGAFACF179 | 3 | — | yes | Δ |
| E1 | | 0.8 | 3 g/L | transparent | ◯ |
| E2 | | 0.5 | 3 g/L | transparent | ◯ |
| C2 | MEGAFACF160 | 3 | — | transparent | Δ |
| E3 | | 0.8 | 3 g/L | transparent | ◯ |
| E4 | | 0.5 | 3 g/L | transparent | ◯ |
| C7 | Phosphanol RS610 | 3 | — | yes | — |
| C8 | Phosphanol RS710 | 3 | — | transparent | X |
| C9 | Phosphanol RE610 | 3 | — | transparent | X |
| C10 | Phosphanol LP700 | 3 | — | transparent | X |
| C11 | Phosphanol RD510V | 3 | — | yes | — |
| C12 | Phosphanol GB520 | 3 | — | yes | — |
| C13 | Triton H-66 | 3 | — | transparent | X |
| C14 | polypropylene glycoldiol type 400 | 3 | — | yes | — |
| C15 | polyethylene glycol 400 | 3 | — | yes | — |
| C16 | Polyti [phonetic] PS-1900 | 3 | — | transparent | X |
| C17 | dipotassium hydrogen phosphate | 3 | — | transparent | X |
| C18 | Ethomeen C-25 | 3 | — | transparent | X |
| C19 | Surfonic N-102 | 3 | — | yes | — |
| C20 | Igepal CO-730 | 3 | — | yes | — |

Note)
MEGAFAC F179 is a perfluoroalkyl-containing oligomer made by Dainippon Ink Chemistry Corp., Ltd.
MEGAFAC F160 is a perfluoroalkyl aminosulfonate made by Dainippon Ink Chemistry Co. Ltd.
Phosphanols are all special phosphoric-ester-type, surface-active agents made by Toho Chemical Industry Co. Ltd.
Polyti [phonetic] PS-1900 is a polystyrene-sulfonate-type polymer anion-type surface-active agent made by Lion Co. Ltd.
Dipotassium hydrogen phosphate is a reagent made by Wako Pure Chemicals Industry Co. Ltd.
Ethomeen C-35 is an ethoxylated (15) cocoalkylamine made by Lion Akzo Co. Ltd.
Surfonic N-102 is an adduct product of nonylphenol with 10.2 mol of ethylene oxide made by Huntsman Corp.
Igepal CO-730 is a polyoxyethylene nonylphenyl ether made by Rhone-Poulenc.

It can be seen from the experimental data that only when a fluorine-free, phosphate-type, surface-active agent and a fluorinated surface-active agent were both contained good results were obtained.

Potential Utility in Industry

As described above, the developing solution of the present invention is used preferably as a developing solution for photoresist. More specifically, it is used preferably for the development of photoresist for the production of wafer level chip size package (WL-CSP), particularly WL-CSP with pier [phonetic] hole or trench.

1. A developer for photoresist comprising an alkali builder, a fluorine-free phosphonic acid or phosphate surface active agent, and a fluorine containing surface active agent.

2-6. (canceled)

7. The developer of claim 1, wherein the alkali builder is potassium hydroxide.

8. The developer of claim 1, wherein the fluorine-free surface active agent is octylphenoxypolyethoxyethyl phosphate.

9. The developer of claim 1, wherein the fluorine containing surface active agent is selected from the group consisting of a perfluoroalkyl containing oligomer, a perfluoroalkyl sulphonate and mixtures thereof.

10. A method to form a relief image comprising: 1) coating an alkali-soluble photoresist composition comprising an epoxy containing compound on a base; 2) exposing the photoresist composition to activating radiation; and 3) developing the photoresist composition on the base body to obtain the relief image, the developer comprises an alkali builder, a fluorine-free phosphonic acid or phosphate surface active agent and a fluorine containing surface active agent.

11. The method of claim 10, wherein the fluorine-free surface active agent is octylphenoxypolyethoxyethyl phosphate.

12. The method of claim 10, wherein the fluorine containing surface active agent is selected from the group consisting of a perfluoroalkyl containing oligomer, a perfluoroalkyl sulphonate and mixtures thereof.

13. A method to form a relief image comprising: 1) coating an alkali-soluble photoresist composition comprising an epoxy containing compound on a base; 2) exposing the photoresist composition to activating radiation; 3) hardening the exposed portions of the photoresist; and 4) developing the photoresist on the base to obtain a relief image, the developer comprises an alkali builder, a fluorine-free phosphonic acid or phosphate surface active agent, and a fluorine containing surface active agent.
